(19) United States
(12) Patent Application Publication
(10) Pub. No.: US 2025/0211168 A1
(43) Pub. Date: Jun. 26, 2025

(54) OSCILLATOR CIRCUIT

(71) Applicant: AMS-OSRAM AG, Premstaetten (AT)

(72) Inventors: Josip MIKULIC, Graz (AT); Gregor SCHATZBERGER, Graz (AT)

(21) Appl. No.: 18/847,628

(22) PCT Filed: Feb. 21, 2023
(86) PCT No.: PCT/EP2023/054299

§ 371 Date: Sep. 16, 2024

(30) Foreign Application Priority Data
Mar. 17, 2022 (DE) 10 2022 106 219.8

(51) Int. Cl. H03B 5/00; H03K 19/21

(52) U.S. Cl. CPC H03B 5/00; H03K 19/21

(57) ABSTRACT

An oscillator circuit is disclosed. The oscillator circuit comprises a first integrator unit, a second integrator unit, and a third integrator unit. The oscillator circuit also comprises a chopped comparator unit comprising first, second and third switching units and corresponding first, second and third comparators. The oscillator circuit also comprises a logic unit configured to receive a first comparator output from the first comparator, a second comparator output from the second comparator and a third comparator output from the third comparator; and use the first, second and third comparator outputs to generate input clock signals and measurement signals for controlling the integrator units and the switching units.

### TECHNICAL FIELD OF THE DISCLOSURE

The present disclosure is in the field of oscillator circuits, and relates in particular to a delay and offset-voltage compensated relaxation oscillator circuit.

### BACKGROUND

Oscillators may be used to generate clock signals that are fundamental to the operation of both analogue and digital circuitry. Increasingly, integrated oscillators, e.g. oscillators formed in silicon-based integrated circuits, are replacing known crystal oscillators.

Advantageously, such integrated oscillators may require less power-up time, consume less power, and be relatively cheap to implement in comparison to crystal oscillators.

Such integrated oscillators may commonly be implemented as relaxation oscillators. In an example, a prior art relaxation oscillator may generally operate by charging and discharging a capacitor to a predefined reference voltage, wherein the reference voltage may be provided to a comparator as input to detect if the capacitor has been charged or discharged beyond a/the respective reference voltage. An output of the comparator may be used to indicate whether the capacitor is to be charged or discharged.

Relaxation oscillators may offer a good compromise of fast start-up, low power consumption, compact area, and other parameters critical for modern consumer applications. However, an accuracy and stability of the output frequency of such relaxation oscillators may be limited by non-ideal characteristics of the comparator. For example, comparators typically exhibit offset voltages and at least some propagation delay, which can directly impact an output of the oscillator.

Furthermore, such detrimental effects due to the non-ideal characteristics of the comparators may become more pronounced at relatively low-voltage technology nodes, e.g. 1.2 volts, 1.0 volts, 0.8 volts or even lower voltages, as may typically be found in CMOS technology nodes below approximately 100 nanometres.

It is therefore desirable to provide a relaxation oscillator circuit wherein performance is optimised by cancelling or at least limiting any offset voltage and propagation delay incurred by the comparator stage. Furthermore, it is desirable that such a relaxation oscillator circuit is suitable for reuse in relatively low-voltage circuits, such as 1.2 volts and below.

It is therefore an aim of at least one embodiment of at least one aspect of the present disclosure to obviate or at least mitigate at least one of the above identified shortcomings of the prior art.

### SUMMARY

The present disclosure is in the field of oscillator circuits, and relates in particular to a delay and offset-voltage compensated relaxation oscillator circuit suitable for use in integrated devices and sensor front-ends.

According to a first aspect of the disclosure, there is provided an oscillator circuit, comprising: a first integrator unit configured to charge a first capacitor at a first integration node; a second integrator unit configured to charge a second capacitor at a second integration node; and a third integrator unit configured to charge a third capacitor at a third integration node.

The oscillator circuit also comprises a chopped comparator unit comprising: a first switching unit configurable to couple a first reference voltage and one of the first integration node and the second integration node to a first comparator; a second switching unit configurable to couple a second reference voltage and one of the first integration node or the second integration node to a second comparator; and a third switching unit configured to couple the third integration node and the second reference voltage to a third comparator.

The oscillator circuit also comprises a logic unit configured to: receive a first output from the first comparator, a second output from the second comparator and a third output from the third comparator; and use the first, second and third outputs to generate input clock signals and measurement signals for controlling the integrator units and the switching units.

Advantageously, the disclosed circuit, may effectively compensate for delay and offset induced by the comparators. Furthermore, the disclosed circuit may be particularly suitable for use in low voltage applications, as described in more detail below.

The second reference voltage may be half of the voltage level of the first reference voltage.

The first switching unit and the second switching unit may be configurable to enable a simultaneous comparison of the first integration node with the first reference voltage and the second reference.

The first switching unit and the second switching unit may be configurable to enable a simultaneous comparison of the second integration node with the first reference voltage and the second reference voltage.

The third integrator unit may be configured as a replica integrator for replicating the first integrator unit and/or the second integrator unit.

That is, the third integrator unit may be formed from the same components and configured to operate is a substantially similar way to the first integrator unit and/or the second integrator unit, as described in more detail below.

The first capacitor, the second capacitor and the third capacitor may have the same storage capacity. The first switching unit, second switching unit and the third switching unit may be substantially identical. The first comparator, the second comparator and the third comparator may be substantially identical.

As such, variations in electrical characteristics of the first, second and third integrator unit will behave substantially the same way over a full range of voltage and temperate operating conditions.

The logic unit may be configured to generate a first input clock signal. The logic unit may be configured to generate a second input clock signal. The logic unit may be configured to generate a third input clock signal. The logic unit may be configured to generate a fourth input clock signal. The logic unit may be configured to generate a first measurement signal. The logic unit may be configured to generate a second measurement signal.

The first integrator unit may comprise a first current source coupled to a supply reference, and a first switch for coupling the first current source to the first capacitor, the first switch controlled by an inverse of the first input clock signal generated by the logic unit.

The first integrator unit may comprise a second switch configurable to discharge the first capacitor to a ground reference, the second switch controlled by the first input clock signal.

The first integrator unit may comprise a second current source coupled to the supply reference and having a third switch for coupling the second current source to the first capacitor, the third switch controlled by the second measurement signal.

The second integrator unit may comprise a third current source coupled to the supply reference, and a fourth switch for coupling the third current source to the second capacitor, the fourth switch controlled by the first input clock signal.

The second integrator unit may comprise a fifth switch configurable to discharge the second capacitor to the ground reference, the fifth switch controlled by an inverse of the first input clock signal.

The second integrator unit may comprise a fourth current source coupled to the supply reference and having a sixth switch for coupling the fourth current source to the second capacitor, the sixth switch controlled by the first measurement signal.

The third integrator unit may comprise a fifth current source coupled to the supply reference, and a seventh switch for coupling the fifth current source to the third capacitor, the seventh switch controlled by the fourth input clock signal.

The third integrator unit may comprise an eighth switch configurable to discharge the third capacitor to the ground reference, the eighth switch controlled by an inverse of the fourth input clock signal.

Compared to prior art integrator units implemented in relaxation oscillators, the above described first, second and third integrator units do not have current sources implemented between the respective integration nodes and a ground reference. That is, only switches are implemented between the respective integration nodes and the ground references. This makes the disclosed oscillator circuit particularly well suited to low-voltage applications, because the switches are suited to operating in such conditions. This may enable any reference voltage to which integration nodes are compared (as described below) to be particularly low, for example 100 mV, 250 mV, or the like. In prior art circuits, such low voltage operation would not have been possible, because any current source operating between the integration modes and the ground reference would have insufficient voltage to operate, e.g. would not even meet its saturation requirements.

When the first input clock signal is low, the first switching unit may operate such that a first voltage at the first integration node is received at a non-inverting input of the first comparator and the reference voltage is received at an inverting input of the first comparator.

When the first input clock signal is high, the first switching unit may operate such that the reference voltage is received at the non-inverting input of the first comparator and a second voltage at the second integration node is received at an inverting input of the first comparator.

When the second input clock signal is low, the second switching unit may operate such that the first voltage at the first integration node is received at a non-inverting input of the second comparator and the second reference voltage is received at an inverting input of the second comparator.

When the second input clock signal is high, the second switching unit may operate such that the second reference voltage is received at the non-inverting input of the second comparator and the second voltage at the second integration node is received at an inverting input of the second comparator.

When a third input clock signal is low, the third switching unit may operate such that a third voltage at the third integration node is received at a non-inverting input of the third comparator and the second reference voltage is received at an inverting input of the second comparator.

When the third input clock signal is high, the third switching unit may operate such that the second reference voltage is received at the non-inverting input of the third comparator and the third voltage is received at an inverting input of the third comparator.

Advantageously, the above-described configuration may effectively cancel any effects of offset voltage of the comparators. This is because each comparator may be configured such that in a first half-cycle in which an integrating node is at the non-inverting input and a reference voltage is at the inverting input, and then in a second half-cycle the inputs to the comparator are swapped such that an integrating node is at the inverting input and a reference voltage is at the non-inverting input. As such, although there may be a difference between each half-cycle, when summed together any offset voltage is effectively cancelled.

The logic unit may be configured to generate a further clock signal having a frequency twice that of the first input clock signal.

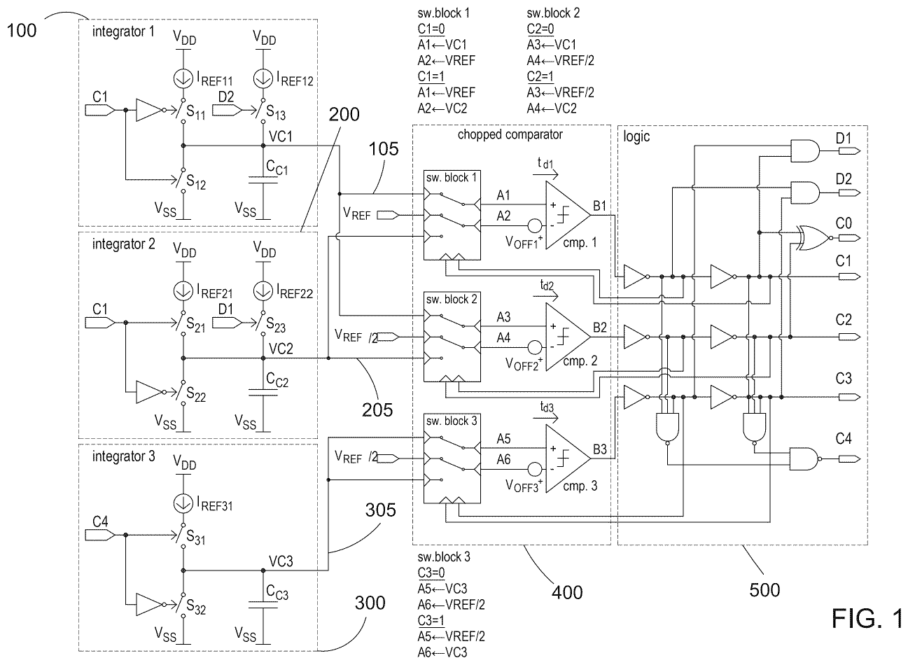

Advantageously, the disclosed oscillator circuit, which is described in more detail below with reference to the example embodiment of FIG. 1, may provide a high frequency output that is twice a frequency of the highest frequency input clock signal used to control the integrator units and/or switching units. That is, the disclosed circuit may provide a relatively high frequency output without incurring substantial power consumption.

The logic unit may be configured such that a logical value of the first input clock signal is equal to a logical value of the first output.

In some examples, the first input clock signal may be provided as a clock signal to a device in which the oscillator circuit is implemented.

The logic unit may be configured such that a logical value of the second input clock signal is equal to a logical value of the second output.

In some examples, the second input clock signal may additionally or alternatively be provided as a clock signal to a device in which the oscillator circuit is implemented.

The logic unit may be configured such that a logical value of the third input clock signal is equal to a logical value of the third output.

The logic unit may be configured such that a logical value of the fourth input clock signal is equal to a logical NAND of: a logical NAND of the first, second and third input clock signals; and a logical NAND of the inverse of each of the first, second and third input clock signals.

The logic unit may be configured such that a logical value of the further clock signal is equal to a logical XNOR of the first input clock signal and the second input clock signal.

The logic unit may be configured such that a logical value of the first measurement signal is equal to a logical AND of the first input clock signal and an inverse of the third input clock signal.

The logic unit may be configured such that a logical value of the second measurement signal is equal to a logical AND of an inverse of the first input clock signal and the third input clock signal.

According to a second aspect of the disclosure, there is provided a device comprising the oscillator circuit according to the first aspect. The oscillator circuit may typically be configured to provide a clock signal having a frequency of at least 1 MHz. In some embodiments, the oscillator circuit may be configured to provide a clock signal having a frequency of less than 1 MHz. In some examples, the oscillator circuit may be provided with a supply voltage of 1.2 volts, 1.0 volts or less.

That is, the disclosed oscillator circuit is suitable for implementation in advanced technology nodes, wherein a supply voltage may be relatively low, such as at 1 volt or even less. Furthermore, the disclosed oscillator circuit is capable of simultaneously operating at such low voltages while also operating in a MHz frequency range.

The device may be, or may be component of, an integrated circuit, such as a system-on-chip, a processor, a microcontroller, and ASIC, a sensor, or a sensor front-end.

The above summary is intended to be merely exemplary and non-limiting. The disclosure includes one or more corresponding aspects, embodiments or features in isolation or in various combinations whether or not specifically stated (including claimed) in that combination or in isolation. It should be understood that features defined above in accordance with any aspect of the present disclosure or below relating to any specific embodiment of the disclosure may be utilized, either alone or in combination with any other defined feature, in any other aspect or embodiment or to form a further aspect or embodiment of the disclosure.

### BRIEF DESCRIPTION OF THE PREFERRED EMBODIMENTS

These and other aspects of the present disclosure will now be described, by way of example only, with reference to the accompanying drawings, wherein:

FIG. 1 depicts an example of a relaxation oscillator circuit, according to an embodiment of the disclosure;

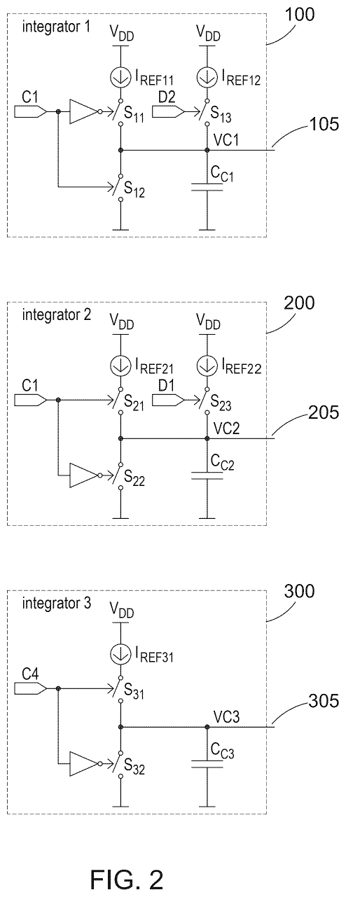

FIG. 2 depicts first, second and third integrator units of the relaxation oscillator circuit of FIG. 1;

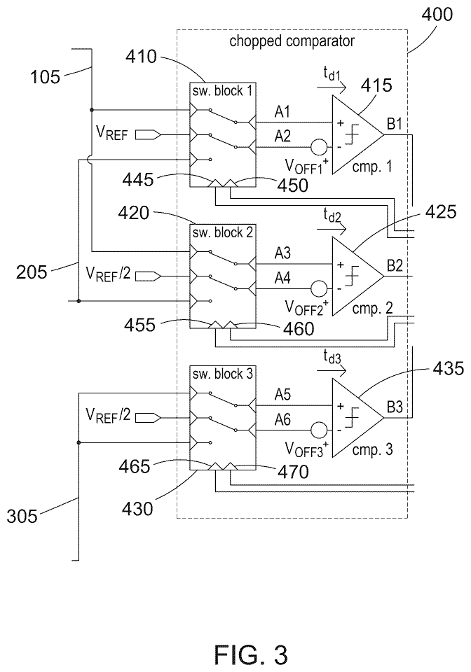

FIG. 3 depicts a chopped comparator unit of the relaxation oscillator circuit of FIG. 1;

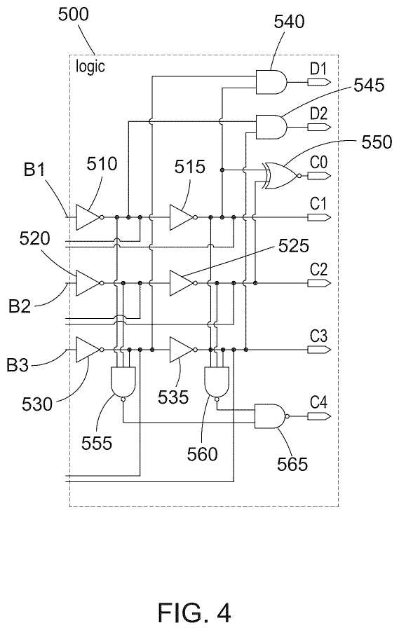

FIG. 4 depicts a logic unit of the relaxation oscillator circuit of FIG. 1; and

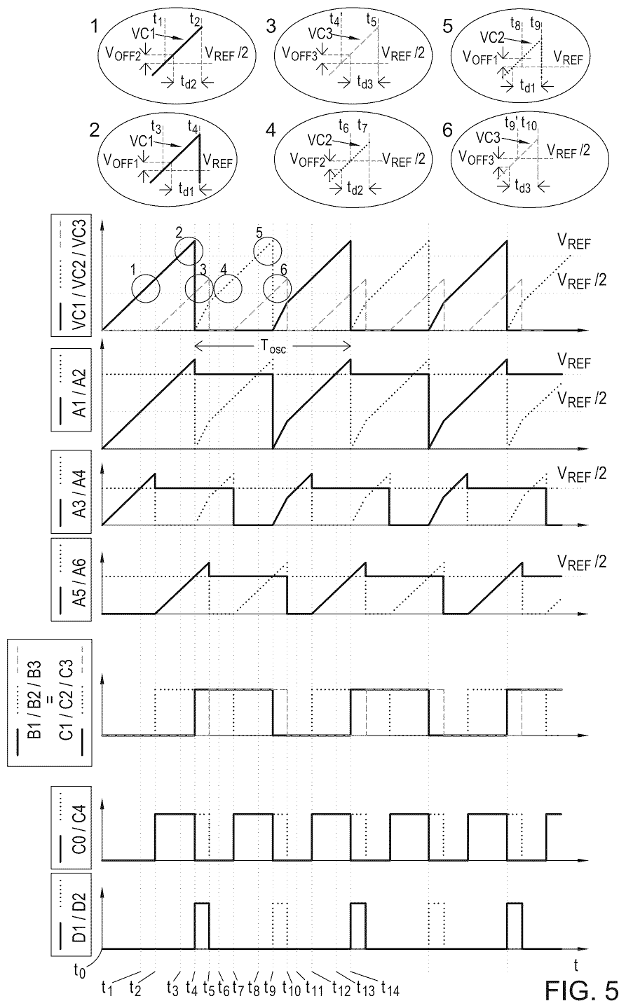

FIG. 5 depicts signal waveforms corresponding to operation of the relaxation oscillator circuits of FIGS. 1 to 4; and

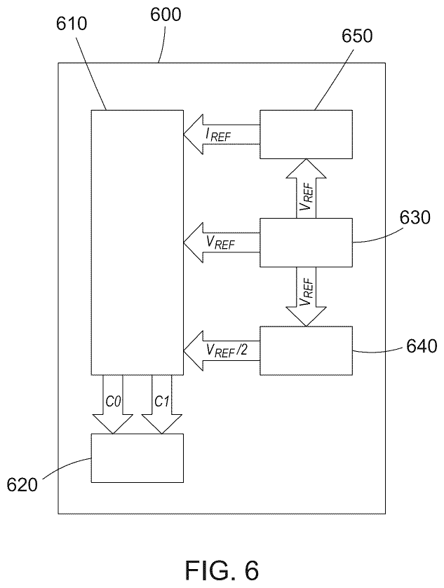

FIG. 6 depicts a device comprising an oscillator circuit according to an example of an embodiment of the disclosure.

### DETAILED DESCRIPTION OF THE PREFERRED EMBODIMENTS

FIG. 1 depicts an example of an oscillator circuit, according to an embodiment of the disclosure. The oscillator circuit comprises a first integrator unit 100, a second integrator unit 200 and a third integrator unit 300. The oscillator circuit also comprises a chopped comparator unit 400 and a logic unit 500.

FIG. 2 depicts a magnified view of the first, second and third integrator units 100, 200, 300 of the oscillator circuit of FIG. 1.

The first integrator unit 100 comprises a first capacitor C_{C1}, and an arrangement of current sources and switches for charging and discharging the first capacitor C_{C1}, to control a first voltage VC1 at a first integration node 105.

The first integrator unit 100 comprises a first current source I_{REF11}. The first current source I_{REF11} is coupled to a supply reference V_{DD}. A first switch S₁₁ is provided for selectively coupling the first current source I_{REF11} to the first capacitor C_{C1}.

In some embodiments, the supply reference V_{DD} may be a relatively low voltage that may be associated with an advanced semiconductor fabrication node, e.g. 90 nm, 40 nm, 22 nm or beyond. The supply reference V_{DD} may, for example, be 1.2V, 1.0V, 0.8V, or even lower.

The first switch controlled by an inverse of a first input clock signal C1, generation of which will be described in more detail below.

The first integrator unit 100 also comprises a second switch S₁₂ configurable to discharge the first capacitor C_{C1} to a ground reference VSS. The ground reference may be at 0 volts relative to the supply reference V_{DD}. The second switch is controlled by the first input clock signal C1.

The first integrator unit 100 also comprises a second current source I_{REF12} coupled to the supply reference V_{DD}. A third switch S₁₃ is provided for selectively coupling the second current source to the first capacitor C_{C1}, e.g. to charge the first capacitor C_{C1}. The third switch S₁₃ is controlled by a second measurement signal D2, generation of which will be described in more detail below.

As such, by controlling the first input clock signal C1 and the second measurement signal D2, the first integrator unit 100 may be configured to charge and discharge the first capacitor C_{C1} thereby defining the first voltage VC1 at the first integration node 105.

The second integrator unit 200 comprises a second capacitor C_{C2}, and an arrangement of current sources and switches for charging and discharging the second capacitor C_{C2}, to control a second voltage VC2 at a second integration node 205.

The second integrator unit 200 comprises a third current source I_{REF21}. The third current source I_{REF21} is coupled to the supply reference V_{DD}. A fourth switch S₂₁ is provided for selectively coupling the third current source I_{REF21} to the second capacitor C_{C2}.

The fourth switch is controlled by the first input clock signal C1.

The second integrator unit 200 also comprises a fifth switch S₂₂ configurable to discharge the second capacitor C_{C2} to the ground reference VSS. The fifth switch is controlled by an inverse of the first input clock signal C1.

The second integrator unit 200 also comprises a fourth current source I_{REF22} coupled to the supply reference V_{DD}. A sixth switch S₂₃ is provided for selectively coupling the third current source to the second capacitor C_{C2}, e.g. to charge the second capacitor C_{C2}. The sixth switch S₁₃ is controlled by a first measurement signal D1, generation of which will be described in more detail below.

As such, by controlling the first input clock signal C1 and the first measurement signal D1, the second integrator unit 200 may be configured to charge and discharge the second capacitor C_{C2} thereby defining the second voltage VC2 at the second integration node 205.

The third integrator unit 300 comprises a third capacitor C_{C3}, and an arrangement of a current source and switches for charging and discharging the third capacitor C_{C3}, to control a voltage VC3 at a third integration node 305.

The third integrator unit 300 comprises a fifth current source I_{REF31}. The fifth current source I_{REF31} is coupled to the supply reference V_{DD}. A seventh switch S₃₁ is provided for selectively coupling the fifth current source I_{REF31} to the third capacitor C_{C3}.

The seventh switch is controlled by a fourth input clock signal C4, generation of which will be described in more detail below.

The second integrator unit 200 also comprises an eighth switch S₃₂ configurable to discharge the third capacitor CCs to the ground reference VSS. The eighth switch S₃₂ is controlled by an inverse of the fourth input clock signal C4.

As such, by controlling the fourth input clock signal C4, the third integrator unit 300 may be configured to charge and discharge the third capacitor CCs thereby defining the voltage VC3 at the third integration node 305.

The third integrator unit 300 may be effectively configured as a “replica integrator”, e.g. an integrator configured as a replica of the first integrator unit 100 and the second integrator unit 200.

For example, components of the third integrator unit 300 may be substantially identical to components of the first integrator unit 100 and the second integrator unit 200. For example, third capacitor CCs has a same storage capacity as the first capacitor C_{C1} and the second capacitor C_{C2}.

FIG. 3 depicts a magnified view of the chopped comparator unit 400 of the oscillator circuit of FIG. 1.

The chopped comparator unit 400 comprises a first switching unit 410.

The chopped comparator unit 400 comprises a first comparator 415.

The first switching unit 410 has an input coupled to the first integration node 105, an input coupled to a first reference voltage VREF, and an input coupled to the second integration node 205.

The first switching unit 410 has a first switch output A1, which is coupled to a non-inverting input of the first comparator 415.

The first switching unit 410 has a second switch output A2, which is coupled to an inverting input of the first comparator 415.

The first switching unit 410 has control inputs 445, 450. A control input 445 corresponds to a first input clock signal C1, generation of which is described in more detail below. A control input 450 corresponds to an inverse of the first input clock signal C1.

The first switching unit 410 can be configured to either: connect the first integration node 105 to the first switch output A1 and the reference voltage V_{REF} at the second input to the second switch output A2 when the first input clock signal C1 is low, e.g. a logical low or ‘0’; or connect the reference voltage V_{REF} to the first switch output A1 and the second integration node 205 to the second switch output A2.

As such, when the first input clock signal C1 is low, the first switching unit 410 operates such that the first voltage VC1 at the first integration node 105 is received at the non-inverting input of the first comparator (415) and the reference voltage V_{REF} IS received at an inverting input of the first comparator 415, and when the first input clock signal C1 is high, the first switching unit 410 operates such that the reference voltage V_{REF} is received at the non-inverting input of the first comparator 415 and the second voltage VC2 at the second integration node 205 is received at an inverting input of the first comparator 415.

A first comparator output B1 from the first comparator 415 is provided to the logic unit 500.

Also depicted in FIGS. 1 and 3 for purposes of illustration only is a first voltage offset V_{OFF1} at the inverting input to the first comparator 415. The first voltage offset V_{OFF1} is depicted to represent an inherent offset that the first comparator 415 may exhibit, and is not an actual component of the circuit per se.

The chopped comparator unit 400 comprises a second switching unit 420.

The chopped comparator unit 400 comprises a second comparator 425.

The second switching unit 420 has an input coupled to the first integration node 105, an input coupled to a second reference voltage V_{REF/2}, and an input coupled to the second integration node 205.

The second switching unit 420 has a third switch output A3, which is coupled to a non-inverting input of the second comparator 425.

The second switching unit 420 has a fourth switch output A4, which is coupled to an inverting input of the second comparator 425.

The second switching unit 420 has control inputs 455, 460. A control input 455 corresponds to a second input clock signal C2, generation of which is described in more detail below. A control input 460 corresponds to an inverse of the second input clock signal C2.

The second switching unit 420 can be configured to either: connect the first integration node 105 to the third switch output A3 and the second reference voltage V_{REF}/2 to the fourth switch output A4 when the second input clock signal C2 is low, e.g. a logical low or ‘0’; or connect the second reference voltage V_{REF}/2 to the third switch output A3 and the second integration node 205 to the fourth switch output A4.

As such, when the second input clock signal C2 is low, the second switching unit 420 operates such that the first voltage VC1 at the first integration node 105 is received at the non-inverting input of the second comparator 425 and the second reference voltage V_{REF}/2 is received at an inverting input of the second comparator 425, and when the second input clock signal C2 is high, the second switching unit 420 operates such that the second reference voltage V_{REF}/2 is received at the non-inverting input of the second comparator 425 and the second voltage VC2 at the second integration node 205 is received at the inverting input of the second comparator 425.

A second comparator output B2 from the second comparator 425 is provided to the logic unit 500.

Also depicted in FIGS. 1 and 3 for purposes of illustration only is a second voltage offset V_{OFF} at the inverting input to the first comparator 415. The second voltage offset V_{OFF2} is depicted to represent an inherent offset that the second comparator 425 may exhibit, and is not an actual component of the circuit per se.

Based on the state of the first input clock signal C1 and the second input clock signal C2, the first switching unit 410 and the second switching unit 420 are configurable to enable a simultaneous comparison of the first integration node 105 with the first reference voltage V_{REF} and the second reference V_{REF}/2, and also a simultaneous comparison of the second integration node 205 with the first reference voltage V_{REF} and the second reference voltage V_{REF}/2.

The chopped comparator unit 400 comprises a third switching unit 430.

The first switching unit 410, the second switching unit 420 and the third switching unit 430 are substantially identical.

The chopped comparator unit 400 comprises a third comparator 435.

The first comparator 415, the second comparator 425 and the third comparator 435 are also substantially identical, e.g. formed from the same circuits and exhibiting substantially the same electrical characteristics.

The third switching unit 430 has an input coupled to the third integration node 305, an input coupled to a second reference voltage V_{REF}/2, and another input coupled to the third integration node 305.

In example embodiments, the second reference voltage V_{REF}/2 is half of the voltage level of the first reference voltage VREF. The reference voltage V_{REF} and the second reference voltage V_{REF}/2 may be provided to the oscillator circuit by a further reference supply (not shown). For example, a known power supply, regulator, or band-gap reference may be provided to generate reference voltage V_{REF} and the second reference voltage V_{REF}/2.

The third switching unit 430 has a fifth switch output A5, which is coupled to a non-inverting input of the third comparator 435.

The third switching unit 430 has a sixth switch output A6, which is coupled to an inverting input of the third comparator 435.

The third switching unit 430 has control inputs 465, 470. A control input 465 corresponds to a third input clock signal C3, generation of which is described in more detail below. A control input 470 corresponds to an inverse of the third input clock signal C3.

The third switching unit 430 can be configured to either: connect the third integration node 305 to the fifth switch output A5 and the second reference voltage V_{REF}/2 to the sixth switch output A6 when the third input clock signal C3 is low, e.g. a logical low or ‘0’; or connect the second reference voltage V_{REF}/2 to the fifth switch output A5 and the third integration node 305 to the sixth switch output A6.

As such, when the third input clock signal C3 is low, the third switching unit 430 operates such that the third voltage VC3 at the third integration node 305 is received at the non-inverting input of the third comparator 435 and the second reference voltage V_{REF}/2 is received at an inverting input of the third comparator 435, and when the third input clock signal C3 is high, the third switching unit 430 operates such that the second reference voltage V_{REF}/2 is received at the non-inverting input of the third comparator 435 and the third voltage VC3 at the third integration node 305 is received at the inverting input of the third comparator 435.

A third comparator output B3 from the third comparator 435 is provided to the logic unit 500.

Again, also depicted in FIGS. 1 and 3 for purposes of illustration only is a third voltage offset V_{OFF3} at the inverting input to the third comparator 435. The third voltage offset V_{OFF3} is depicted to represent an inherent offset that the third comparator 435 may exhibit, and is not an actual component of the circuit per se.

The oscillator circuit comprises a logic unit 500. In the example embodiment, the logic unit is depicted as combinational logic, e.g. Boolean circuitry comprising a variety of NOT (inverter), AND, NAND, and XNOR (exclusive NOR) gates.

The logic unit receives the first comparator output B1 from the first comparator 415. The first comparator output B1 is connected to an input of a first NOT gate 510. An output of the first NOT gate 510 is connected to an input of a second NOT gate 515. An output of the second NOT gate 515 is the first input clock signal C1, for controlling the first switch S₁₁, the second switch S₁₂, the third switch S₂₁ and the first switching unit 410. As such, a logical value of the first input clock signal C1 is equal to a logical value of the first comparator output B1.

The logic unit receives the second comparator output B2 from the second comparator 425. The second comparator output B2 is connected to an input of a third NOT gate 520. An output of the third NOT gate 520 is connected to an input of a fourth NOT gate 525. An output of the fourth NOT gate 525 is the second input clock signal C2, for controlling the second switching unit 420. As such, a logical value of the second input clock signal C2 is equal to a logical value of the second comparator output B2.

The logic unit receives the third comparator output B3 from the third comparator 435. The third comparator output B3 is connected to an input of a fifth NOT gate 530. An output of the fifth NOT gate 530 is connected to an input of a sixth NOT gate 535. An output of the sixth NOT gate 535 is the third input clock signal C3, for controlling the third switching unit 430. As such, a logical value of the third input clock signal C3 is equal to a logical value of the third comparator output B3.

The outputs of the second and fifth NOT gates 515, 530 are connected to inputs of a first AND gate 540. An output of the first AND gate 540 is the first measurement signal D1 for controlling the sixth switch S₁₃. As such, a logical value of the first measurement signal D1 is equal to a logical AND of the first input clock signal C1 and an inverse of the third input clock signal C3.

The outputs of the first and sixth NOT gates 510, 535 are connected to inputs of a second AND gate 545. An output of the second AND gate 545 is the second measurement signal D2 for controlling the third switch S₁₃. As such, a logical value of the second measurement signal D2 is equal to a logical AND of the first input clock signal C1 and the third input clock signal C3.

The outputs of the second and fourth NOT gates 515, 525 are connected to inputs of a first XNOR gate 550. An output of the first XNOR gate 550 is a further clock signal C0. The further clock signal C0 exhibits a frequency twice that of the first input clock signal C1.

Finally, outputs of the first, third and fifth NOT gates 510, 520, 530 are connected to inputs of a first three-input NAND gate 555. Outputs of the second, fourth and sixth NOT gates 515, 525, 535 are connected to inputs of a second three-input NAND gate 560.

Outputs of the first and second three-input NAND gates 555, 560 are connected to inputs of a first two-input NAND gate 565. An output of the first two-input NAND gate 565 is the fourth input clock signal C4 for controlling the seventh switch S_{31.}, and where in an inverse of the fourth input clock signal C4 controls the eighth switch S₃₂

In example embodiments described above, the current sources, e.g. I_{REF11}, I_{REF12}, I_{REF21}, I_{REF22}, I_{REF31} may be provided to the oscillator circuit by a further reference supply (not shown). For example, a known power supply, regulator, band-gap reference or voltage-to-current converter may be provided to generate the current sources. Further examples are described in more detail below with reference to FIG. 6.

Operation of the relaxation oscillator of FIGS. 1 to 4 described with reference to the signal waveforms of FIG. 5.

At an initial time (t=t₀), it is presumed that all the signals are forced to the initial state by a start-up circuit (not shown).

Initially, integration takes place within the first integrator unit 100 in a time interval from t₀ to t₂. As such, the first voltage VC1 at the first integration node 105 rises linearly, a rate of increase having the nominal slope ΔV/Δt=I_{REF}/C_{REF}. As described above, the first, second and third capacitors C_{C1}, C_{C2}, Ccs all have substantially the same capacity, hereafter referred to as C_{REF}. Similar, the first, second, third, fourth and fifth current sources I_{REF11}, I_{REF12}, I_{REF21}, I_{REF22}, I_{REF31} are substantially the same, and therefore a current from each source is hereafter referred to as I_{REF}.

Due to the initial configuration of the first switching unit 410 and the second switching unit 420 (e.g. while C1 is low and C2 are low), the first voltage VC1 is present at the first switch output A1 and the third switch output A3.

Meanwhile, the second and third integrator blocks remain idle as the second integration node 205 is shorted to ground by the sixth switch S₂₂ and the third integration node 305 is shorted to ground by the eighth switch S₃₂, e.g. the second voltage VC2 and the third voltage VC3 correspond to the ground reference VSS.

At a subsequent first time (t=t₁) the first voltage VC1 at the first integration node 105 signal which is present at the third switch output A3 becomes equal to the second reference voltage V_{REF}/2 which is present at the fourth switch output A4.

Nevertheless, the second comparator output B2 from the second comparator 425 changes state at t=t₂ as a result of the non-ideal characteristics of the second comparator, namely a propagation delay t_{d2} and a voltage-offset, e.g. the second voltage offset V_{OFF2}. The timing can be expressed as:

$${t}_{2} = \frac{( 0.5 \cdot {V}_{REF} + {V}_{OFF 2} ) \cdot {C}_{REF}}{{I}_{REF}} + {t}_{d 2} \qquad ( 1 )$$

Following the change of the of the second comparator output B2, after t=t₂, the second switching unit 420 changes state, such that the second reference voltage V_{REF}/2 is present at the third switch output A3 and the voltage VC2 at the second integration node 205 is present at the fourth switch output A4. Meanwhile, the integrating signal, e.g. the voltage VC1 at the first integration node 105 that is present at the first switch output A1 continues to rise linearly having the same slope as prior to t=t₂.

Also, at time t=t₂ the fourth input clock signal C4 transitions from low to high, starting integration within the third integrator unit 300 such that the third voltage VC3 present at the fifth switch output A5 also rises linearly having the nominal slope ΔV/Δt=I_{REF}/C_{REF}. That is, at time t=t₂ the third integrator unit 300 replicates the integration behaviour of the first integrator unit 100, with a phase delay corresponding to t₂.

At a subsequent time t=t₃, the first voltage VC1 which is present at the first switch output A1 becomes equal to the reference voltage V_{REF} that is present at the second switch output A2. Nevertheless, the first comparator output B1 changes state at t=t₄ as a result of the non-ideal characteristics of the first comparator 415, namely the propagation delay t_{d1} and a voltage-offset, e.g. the first voltage offset V_{OFF1}. Therefore, the following expression is valid:

$${t}_{4} = \frac{( {V}_{REF} + {V}_{OFF 1} ) \cdot {C}_{REF}}{{I}_{REF}} + {t}_{d 1} \qquad ( 2 )$$

After the change of the first comparator output B1 to high, the first switching unit 410 changes state, resulting in the first reference voltage V_{REF} being present at the first switch output A1 and the second voltage VC2 at the second integration node 205 being present at the second switch output A2. As a result, integration starts to take place within the second integrator block 200.

Due to the state of the first output signal B1 and the third output signal B3, the measurement signal D1 is set to high. As such, the second voltage VC2 at the second integration node 205 and present as the second switch output A2 rises linearly having the slope ΔV/Δt=2I_{REF}/C_{REF}.

Meanwhile, at t=t₄′, the third voltage VC3 at the third integration node 305, e.g the “replica integrating voltage”, which is present at the fifth switch output A5 becomes equal to V_{REF}/2 which is present at the sixth switch output A6.

Note that time instance t₄′ is same as ta in the case that the first comparator 415, the second comparator 425 and the third comparator 435 are presumed identical. However, a timing of the first, second and third comparators may differ slightly due to variations in properties of the comparators.

Due to the offset-voltage, e.g. V_{OFF3}, and a propagation delay of the third comparator, the third comparator output B3 changes state from low to high at t=t₅. Therefore, the following is valid:

$${t}_{5} - {t}_{2} = \frac{( 0.5 \cdot {V}_{REF} + {V}_{OFF 3} ) \cdot {C}_{REF}}{{I}_{REF}} + {t}_{d 3} \qquad ( 3 )$$

Following the change of the third comparator output B3, the third switching unit 430 changes state, such that the third voltage VC3 is present at the sixth output and the second reference voltage V_{REF}/2 is present at the fifth switch output A5. Also, the fourth output C4 transitions from high to low, meaning that the third integration node 305 is shorted to ground, e.g. the third integration voltage VC3 corresponds to the ground reference VSS, and the third integrator 300 is idle.

At this stage, the first measurement signal D1 transitions from high to low, making the duration of the measurement signal equal to:

$${t}_{D 1} = {t}_{5} - {t}_{4} = ( {t}_{5} - {t}_{2} ) + ( {t}_{2} - {t}_{0} ) - ( {t}_{4} - {t}_{0} ) \qquad ( 4 )$$

t_{D1} can therefore be represented as follows.

$${t}_{D 1} = {t}_{5} - {t}_{4} = \frac{( - {V}_{OFF 1} + {V}_{OFF 2} + {V}_{OFF 3} ) \cdot {C}_{REF}}{{I}_{REF}} - {t}_{d 1} + {t}_{d 2} + {t}_{d 3} \qquad ( 5 )$$

The second voltage VC2 at a time t=t₅, hereafter denoted VC2 (t₅), can be calculated as a function of the slope of the integrating signal and the duration of the measurement signal, and can be represented as follows

$$VC 2 ( {t}_{5} ) = \frac{2 {I}_{REF} ( - {t}_{d 1} + {t}_{d 2} + {t}_{d 3} )}{{C}_{REF}} + 2 ( - {V}_{OFF 1} + {V}_{OFF 2} + {V}_{OFF 3} ) . \qquad ( 6 )$$

Also, after time t=t₅, the second voltage VC2 at the second integration node 205 which is present at the second switch output A2 continues to rise having the nominal slope ΔV/Δt=I_{REF}/C_{REF}.

At a subsequent time t=t₆, the second voltage VC2 present at the fourth switch output A4 becomes equal to V_{REF}/2 which is present at the third switch output A3.

At a subsequent time t=t₇, the second comparator output B2 changes state from high to low as a result of the non-ideal characteristics of the second comparator 425, namely a propagation delay t_{d2} and a voltage-offset, e.g. the second voltage offset V_{OFF2}. The timing can be expressed as

$${t}_{7} - {t}_{5} = \frac{( 0.5 \cdot {V}_{REF} - {V}_{OFF 2} - VC 2 ( {t}_{5} ) ) \cdot {C}_{REF}}{{I}_{REF}} + {t}_{d 2} . \qquad ( 7 )$$

Following the change of the second comparator output B2, after t=t₇ the second switching unit 420 changes the state, such that the second reference voltage V_{REF}/2 is present at the fourth switch output A4 and the first voltage VC1 at the first integration node 105 is present at the third switch output A3. Meanwhile, the second voltage VC2 which is present at the second switch output A2 continues to rise linearly having the same slope as prior to t=t₇.

Also, the fourth input clock signal C4 transitions goes from low to high, starting the integration on the third integrator unit 300, such that the third voltage VC3 present at the sixth switch output A6 rises linearly having the nominal slope ΔV/Δt=I_{REF}/C_{REF}.

At a subsequent time t=t₈, the second voltage VC2 which is present at the second switch output A2 becomes equal to the reference voltage V_{REF} which is present at the first switch output A1. As such, the first comparator output B1 from the first comparator 420 transitions from high to low at t=t₉ as a result of the non-ideal characteristics of the first comparator, namely a propagation delay t_{d1} and a voltage-offset, e.g. the first voltage offset V_{OFF1}. Therefore, the following expression is valid:

$${t}_{9} - {t}_{5} = \frac{( {V}_{REF} - {V}_{OFF 1} - VC 2 ( {t}_{5} ) ) \cdot {C}_{REF}}{{I}_{REF}} + {t}_{d 1} \qquad ( 8 )$$

After the transition of the first comparator output B1 to low, the first switching unit 410 changes state, such that the first reference voltage V_{REF} is present at the second switch output A2 and the first voltage VC1 is present at the third switch output A3. As such, the integration starts to take place within the first integrator unit 100.

As a result of the state of the first comparator output B1 and the third comparator output B3, the second measurement signal D2 is set to high. As such, the first voltage VC1 present at the first switch output A1 rises linearly having the slope ΔV/Δt=2I_{REF}/C_{REF}.

Meanwhile, at a time t=t₉′, the third voltage VC3, e.g. the replica integrating voltage, which is present at the sixth switch output A6 becomes equal to the second reference voltage V_{REF}/2 present at the fifth switch output.

Again, note that time t₉′ is same as to in case all comparators are presumed identical, but may in practice slightly differ due to variations in properties of the comparators, e.g. electrical and timing characteristics of the comparators. Due to the offset-voltage and propagation delay of the third comparator 435, the third comparator output B3 changes state from high to low at a time t=t₁₀. Therefore, the following is valid:

$${t}_{10} - {t}_{7} = \frac{( 0.5 \cdot {V}_{REF} - {V}_{OFF 3} ) \cdot {C}_{REF}}{{I}_{REF}} + {t}_{d 3} . \qquad ( 9 )$$

Following the transition of the third comparator output B3 from high to low, the third switching unit 430 changes the state. As such, the third voltage VC3 is present at the fifth switch output A5 and the second reference voltage V_{REF/2} is present at the sixth switch output A6. Also, the fourth input clock signal C4 transitions from high to low, meaning the third integration node 305 is shorted to ground and the third integrator is idle, e.g. the voltage VC3 corresponds to the ground reference V_{SS}.

With this, the second measurement signal D2 transitions from high to low, making the duration of the measurement signal equal to:

$${t}_{D 2} = {t}_{10} - {t}_{9} = ( {t}_{10} - {t}_{7} ) + ( {t}_{7} - {t}_{5} ) - ( {t}_{9} - {t}_{5} ) , \qquad ( 10 )$$

t_{D2} can therefore be represented as follows.

$${t}_{D 2} = \frac{( {V}_{OFF 1} - {V}_{OFF 2} - {V}_{OFF 3} ) \cdot {C}_{REF}}{{I}_{REF}} - {t}_{d 1} + {t}_{d 2} + {t}_{d 3} \qquad ( 11 )$$

The first voltage VC1 at a time t=t₁₀, hereafter denoted VC1 (t₁₀), can be calculated as a function of the slope of the integrating signal and the duration of the measurement signal, and can be represented as follows

$$VC 1 ( {t}_{10} ) = 2 \cdot ( {V}_{OFF 1} - {V}_{OFF 2} - {V}_{OFF 3} ) + \frac{2 {I}_{REF} \cdot ( - {t}_{d 1} + {t}_{d 2} + {t}_{d 3} )}{{C}_{REF}} \qquad ( 12 )$$

Also, after time t=t₁₀, the first voltage VC1 present at the first switch output A1 continues to rise having the nominal slope ΔV/Δt=I_{REF}/C_{REF}.

At a subsequent time t=t₁₃, the first voltage VC1 present at the first switch output A1 becomes equal to the first reference voltage V_{REF} present at the second switch output A2.

Nevertheless, the first comparator output B1 transitions from low to high at t=t₁₄ as a result of the non-ideal characteristics of the first comparator, namely the propagation delay t_{d1} and the first offset voltage V_{OFF1}. Therefore, the following expression is valid:

$${t}_{14} - {t}_{10} = \frac{( {V}_{REF} + {V}_{OFF 1} - VC 1 ( {t}_{10} ) ) \cdot {C}_{REF}}{{I}_{REF}} + {t}_{d 1} \qquad ( 13 )$$

With this, a complete oscillation cycle is described from t₄ to t₁₄. An oscillation period can be calculated by adding segments as follows:

$${T}_{osc} = ( {t}_{5} - {t}_{4} ) + ( {t}_{9} - {t}_{5} ) + ( {t}_{10} - {t}_{9} ) + ( {t}_{14} - {t}_{10} ) \qquad ( 14 )$$

resulting in

$${T}_{osc} = \frac{2 \cdot {V}_{REF} \cdot {C}_{REF}}{{I}_{REF}} + 4 {t}_{d 1} - 2 {t}_{d 2} - 2 {t}_{d 3} \qquad ( 15 )$$

According to Equation (15), the stability of oscillation period is dependent on the stability of the reference values (V_{REF}, I_{REF}, C_{REF}), together with the relative matching of the three comparator delays (t_{d1}, t_{d2}, t_{d3}). Moreover, the contribution of the offset-voltage of the comparator is completely negated.

FIG. 6 depicts a device 600 comprising an oscillator circuit 610 according to an example of an embodiment of the disclosure. For purposes of example, the device 600 is an integrated circuit. The oscillator 610 may be the oscillator of FIG. 1

The example device 600 comprises further circuitry 620. The further circuitry 620 may, for example, comprise processing circuitry, a peripheral or communications device, a sensor or a sensor front-end, or indeed any synchronous circuitry that may require one or more clock signals provided by the oscillator circuit 610 to operate.

As described above, the disclosed oscillator circuit provided generates various input clock signals C1, C2, C3, C4 and measurement signals D1, D2. Any or all of these signals may be provided as a clock source to the further circuitry 620.

For example, in the embodiment of FIG. 6 the first input clock signal C1 is provided as a clock signal to the further circuitry 620. Also, the further input clock signal C0 is provided as a further clock signal to the further circuitry 620, wherein the further input clock signal C0 has a frequency twice that of the first input clock signal C1.

In an example embodiment, the oscillator circuit 610 may be configured to provide one or more clock signals, e.g. C0, to the further circuitry 620, wherein the one or more clock signals has a frequency of 1 MHz or greater. In other example embodiments, the oscillator circuit 610 may provide the one or more clock signals to the further circuitry 620 wherein at least one of the one or more clock signals has a frequency of less than 1 MHz.

Also depicted is a first reference supply 630 configured to provide the first voltage reference V_{REF} to the oscillator circuit 610. The first voltage reference V_{REF} may be generated by the first reference supply 630 using a regulator, a band-gap reference, or other means known to provide a relatively stable reference voltage. Also depicted is a second reference supply 640 configured to provide the second voltage reference V_{REF/2} to the oscillator circuit 610. In the example embodiment, the first voltage reference V_{REF} is provided to the second reference supply 640, wherein the second reference supply 640 generates the second voltage reference V_{REF/2} from the first voltage reference V_{REF}. In an example, the second reference supply 640 may comprise a regulator, a voltage divider, or the like.

In other examples, the second reference supply 640 may provide the second voltage reference V_{REF/2} to the oscillator circuit 610 without receiving the first voltage reference V_{REF} from the first reference supply 630. In yet further examples, the first voltage reference V_{REF} and/or the second voltage reference V_{REF/2} may be provided to the device 600 by an external reference, e.g. an external voltage regulator or the like.

Also depicted is a third reference supply 650. For purposes of example only, the third reference supply 650 is a Voltage-to-Current (V2I) converter, and is configured to generate a reference current I_{REF} from the voltage reference V_{REF} provided by the first reference supply 630.

The third reference supply 650 is configured to provide the reference current I_{REF} for use by the integrator units of the oscillator circuit 610. For example, referring again to the example oscillator circuit of FIG. 1, I_{REF} provided by the third reference supply 650 may provide the first current source I_{REF11}, the second current source I_{REF12}, the third current source I_{REF21}, the fourth current source I_{REF22} and the fifth current source I_{REF31}, e.g. I_{REF}=I_{REF11}=I_{REF12}=I_{REF21}=I_{REF22}=I_{REF31}.

That is, in the example embodiment of FIG. 6 the reference current I_{REF} that is supplied to the corresponding integrator units within the oscillator core in form of I_{REF11}, I_{REF21}, . . . . I_{REF31}, is generated outside the “oscillator core”, e.g. outside the oscillator circuit of FIG. 1. The reference current I_{REF} may be generated by the third reference supply 650 e.g. the V2I converter, such that reference current I_{REF} is related to the ratio of the reference voltage V_{REF} and the reference resistance R_{REF}

$${I}_{REF} = \frac{{V}_{REF}}{{R}_{REF}} \qquad ( 16 )$$

In this case, Equation 15 can be expressed as Equation 17 below:

$${T}_{osc} = 2 {R}_{REF} {C}_{REF} + 4 {t}_{d 1} - 2 {t}_{d 2} - 2 {t}_{d 3} \qquad ( 17 )$$

The device may be fabricated in an advanced CMOS technology node configured to operate with a relatively low voltage supply (not shown), e.g. 1.2V, 1.0V, 0.8V or even less. The first voltage reference V_{REF} may be substantially lower than the low voltage supply for the device. For example, the first voltage reference V_{REF} may be in the region of 250 mV, 200 mV, 100 mV or even less.

Although the disclosure has been described in terms of particular embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

REFERENCE NUMERALS

| C_{C1} | first Capacitor |
|---|---|
| C_{C2} | second capacitor |
| V_{REF} | first reference voltage |
| V_{REF/2} | second reference voltage |
| V_{OFF1} | first voltage offset |
| V_{OFF2} | second voltage offset |
| V_{OFF3} | third voltage offset |
| A1 | first switch output |
| A2 | second switch output |
| A3 | third switch output |
| A4 | fourth switch output |
| A5 | fifth switch output |
| A6 | sixth switch output |
| B1 | first comparator output |
| B2 | second comparator output |
| B3 | third comparator output |
| C0 | further clock signal |
| C1 | first input clock signal |
| C2 | second input clock signal |
| C3 | third input clock signal |
| C4 | fourth input clock signal |
| D1 | first measurement signal |
| D2 | second measurement signal |
| 100 | first integrator unit |
| 105 | first integration node |
| 200 | second integrator unit |
| 205 | second integration node |
| 300 | third integrator unit |
| 305 | first integration node |
| 400 | chopped comparator unit |
| 410 | first switching unit |
| 415 | first comparator |
| 420 | second switching unit |
| 425 | second comparator |
| 430 | third switching unit |
| 435 | third comparator |
| 445 | control input |
| 450 | control input |
| 455 | control input |
| 460 | control input |
| 465 | control input |
| 470 | control input |
| 500 | logic unit |
| 510 | first NOT gate |
| 515 | second NOT gate |
| 520 | third NOT gate |
| 525 | fourth NOT gate |
| 530 | fifth NOT gate |
| 535 | sixth NOT gate |
| 540 | first AND gate |
| 545 | second AND gate |
| 550 | first XNOR gate |
| 555 | first three-input NAND gate |
| 560 | second three-input NAND gate |
| 565 | first two-input NAND gate |
| 600 | device |
| 610 | oscillator circuit |
| 620 | further circuitry |
| 630 | first reference supply |
| 640 | second reference supply |
| 650 | third reference supply |

1. An oscillator circuit, comprising:
a first integrator unit configured to charge a first capacitor at a first integration node;
a second integrator unit configured to charge a second capacitor at a second integration node;
a third integrator unit configured to charge a third capacitor at a third integration node;
a chopped comparator unit comprising:
a first switching unit configurable to couple a first reference voltage and one of the first integration node and the second integration node to a first comparator;
a second switching unit configurable to couple a second reference voltage and one of the first integration node or the second integration node to a second comparator; and
a third switching unit configured to couple the third integration node and the second reference voltage to a third comparator; and
a logic unit configured to:
receive a first comparator output from the first comparator, a second comparator output from the second comparator and a third comparator output from the third comparator; and
use the first, second and third comparator outputs to generate input clock signals and measurement signals for controlling the integrator units and the switching units.

2. The oscillator circuit of claim 1, wherein the second reference voltage is half of the voltage level of the first reference voltage.

3. The oscillator circuit of claim 1, wherein the first switching unit and the second switching unit are configurable to enable:
a simultaneous comparison of the first integration node with the first reference voltage and the second reference; and
a simultaneous comparison of the second integration node with the first reference voltage and the second reference voltage.

4. The oscillator circuit of claim 1, wherein the third integrator unit is configured as a replica integrator for replicating the first integrator unit and/or the second integrator unit.

5. The oscillator circuit of claim 1, wherein:
the first capacitor, the second capacitor and the third capacitor have the same storage capacity; and/or
the first switching unit, second switching unit and the third switching unit are substantially identical; and/or
the first comparator, the second comparator and the third comparator are substantially identical.

6. The oscillator circuit of claim 1, wherein the logic unit is configured to generate: a first input clock signal, a second input clock signal, a third input clock signal, a fourth input clock signal, a first measurement signal and a second measurement signal.

7. The oscillator circuit of claim 6, wherein the first integrator unit comprises:
a first current source coupled to a supply reference, and a first switch for coupling the first current source to the first capacitor, the first switch controlled by an inverse of the first input clock signal generated by the logic unit;
a second switch configurable to discharge the first capacitor to a ground reference, the second switch controlled by the first input clock signal; and
a second current source coupled to the supply reference and having a third switch for coupling the second current source to the first capacitor, the third switch controlled by the second measurement signal.

8. The oscillator circuit of claim 6, wherein the second integrator unit comprises:
a third current source coupled to the supply reference, and a fourth switch for coupling the third current source to the second capacitor, the fourth switch controlled by the first input clock signal;
a fifth switch configurable to discharge the second capacitor to the ground reference, the fifth switch controlled by an inverse of the first input clock signal; and
a fourth current source coupled to the supply reference and having a sixth switch for coupling the fourth current source to the second capacitor, the sixth switch controlled by the first measurement signal.

9. The oscillator circuit of claim 6, wherein the third integrator unit comprises:
a fifth current source coupled to the supply reference; and a seventh switch for coupling the fifth current source to the third capacitor, the seventh switch controlled by the fourth input clock signal; and
an eighth switch configurable to discharge the third capacitor to the ground reference, the eighth switch controlled by an inverse of the fourth input clock signal.

10. The oscillator circuit of claim 6, wherein:
when the first input clock signal is low, the first switching unit operates such that a first voltage at the first integration node is received at a non-inverting input of the first comparator and the reference voltage is received at an inverting input of the first comparator; and
when the first input clock signal is high, the first switching unit operates such that the reference voltage is received at the non-inverting input of the first comparator and a second voltage at the second integration node is received at an inverting input of the first comparator.

11. The oscillator circuit of claim 6, wherein:
when the second input clock signal is low, the second switching unit operates such that the first voltage at the first integration node is received at a non-inverting input of the second comparator and the second reference voltage is received at an inverting input of the second comparator; and
when the second input clock signal is high, the second switching unit operates such that the second reference voltage is received at the non-inverting input of the second comparator and the second voltage at the second integration node is received at an inverting input of the second comparator.

12. The oscillator circuit of claim 6, wherein:
when the third input clock signal is low, the third switching unit operates such that a third voltage at the third integration node is received at a non-inverting input of the third comparator and the second reference voltage is received at an inverting input of the second comparator; and
when the third input clock signal is high, the third switching unit operates such that the second reference voltage is received at the non-inverting input of the third comparator and the third voltage is received at an inverting input of the third comparator.

13. The oscillator circuit of claim 6, wherein the logic unit is configured to generate a further clock signal having a frequency twice that of the first input clock signal.

14. The oscillator circuit of claim 6, wherein the logic unit is configured such that:
a logical value of the first input clock signal is equal to a logical value of the first comparator output;
a logical value of the second input clock signal is equal to a logical value of the second comparator output;
a logical value of the third input clock signal is equal to a logical value of the third comparator output;
a logical value of the fourth input clock signal is equal to a logical NAND of:
a logical NAND of the first, second and third input clock signals; and
a logical NAND of the inverse of each of the first, second and third input clock signals;
a logical value of the further clock signal is equal to a logical XNOR of the first input clock signal and the second input clock signal;
a logical value of the first measurement signal is equal to a logical AND of the first input clock signal and an inverse of the third input clock signal; and
a logical value of the second measurement signal is equal to a logical AND of the first input clock signal and the third input clock signal.

15. A device comprising the oscillator circuit of claim 1, wherein a supply voltage provided to the oscillator circuit is approximately 1.2 volts or less.
